(19) United States
(12) Patent Application Publication
(10) Pub. No.: US 2025/0301798 A1
(43) Pub. Date: Sep. 25, 2025

(54) SEMICONDUCTOR DEVICE AND POWER SEMICONDUCTOR SYSTEM INCLUDING THE SAME

(71) Applicant: Samsung Electronics Co., Ltd., Suwon-si (KR)

(72) Inventor: In Jun HWANG, Suwon-si (KR)

(73) Assignee: Samsung Electronics Co., Ltd., Suwon-si (KR)

(21) Appl. No.: 18/799,292

(22) Filed: Aug. 9, 2024

(30) Foreign Application Priority Data
Mar. 25, 2024 (KR) 10-2024-0040469

(51) Int. Cl. H01L 27/02; H01L 29/20; H01L 29/778; H03K 17/081

(52) U.S. Cl. CPC H10D 89/911; H03K 17/08104; H10D 30/475; H10D 62/8503

(57) ABSTRACT

A semiconductor device includes a high electron mobility transistor including a gate configured to receive a gate signal, a drain connected to a first terminal, a source connected to a second terminal, and a surge protection circuit configured to change an output capacitance of the high electron mobility transistor based on a voltage between the drain and the source.

### CROSS-REFERENCE TO RELATED APPLICATION

This application claims priority to and the benefit of Korean Patent Application No. 10-2024-0040469 filed in the Korean Intellectual Property Office on Mar. 25, 2024, the entire contents of which are incorporated herein by reference.

### BACKGROUND

Various example embodiments relate, in general, to a semiconductor device and/or a power semiconductor system including the same.

Power devices are used to handle a high voltage and/or a high current, and may perform power conversion and control, etc., in large power systems or high-power electronic devices. The power devices have the ability and durability to handle high power, so they may handle large amounts of current and withstand high voltage.

Most power devices are a silicon (Si)-based power metal-oxide-semiconductor field-effect transistor (MOSFET) or an insulated gate bipolar transistor (IGBT). However, due to limitations in the physical properties of silicon, limitations in the manufacturing process, and the like, it is becoming difficult to increase the efficiency of the silicon-based power devices.

In this regard, a high electron mobility transistor (HEMT) using a heterojunction structure of compound semiconductors are attracting attention.

GaN HEMT devices require or often have high costs, but are efficient in terms of speed and may be suitable for high-speed charging of mobile devices.

### SUMMARY

Various example embodiments attempt to provide a power device capable of being resistant to or less impacted from surge.

According to some example embodiments, a semiconductor device includes a high electron mobility transistor including a gate configured to receive a gate signal, a drain connected to a first terminal, and a source connected to a second terminal, and a surge protection circuit configured to change an output capacitance of the high electron mobility transistor based on a voltage between the drain and the source.

Alternatively or additionally according to various example embodiments, a power semiconductor device includes a high electron mobility transistor including a channel layer, a barrier layer on the channel layer and including a material having an energy band gap different from that of the channel layer, a gate electrode on the barrier layer, a gate semiconductor layer between the barrier layer and the gate electrode, and a source electrode on one side of and a drain electrode on another side of the gate electrode and the source and drain electrode connected to the channel layer; a first capacitor including a first electrode on a first protective layer on the barrier layer, a second protective layer on the first electrode, and a second electrode on the second protective layer; and a first transistor connecting the first capacitor between the drain electrode and the source electrode, the first transistor connecting the first capacitor based on a voltage between the drain electrode and the source electrode.

Alternatively or additionally according to various example embodiments, a power semiconductor system includes a switch controller configured to receive a first driving voltage, a second driving voltage, and a control signal, and to output a gate signal based on the first driving voltage, the second driving voltage, and the control signal, and a power block including a high electron mobility transistor connected between a first power supply voltage and a second power supply voltage configured to be at a level lower than the first power supply voltage, and configured to receive the gate signal as an input and a surge protection circuit connected between a source and a drain of the high electron mobility transistor, and configured to control an output capacitance of the high electron mobility transistor.

### BRIEF DESCRIPTION OF THE DRAWINGS

FIG. 1 is a block diagram schematically illustrating a power semiconductor system according to some example embodiments.

FIG. 2 is a block diagram illustrating a power device according to some example embodiments.

FIG. 3 is a block diagram illustrating in detail the power device according to some example embodiments.

FIG. 4 is a block diagram illustrating a power semiconductor device according to some example embodiments.

FIG. 5 is a circuit diagram illustrating a voltage divider circuit according to some example embodiments.

FIG. 6 is a circuit diagram illustrating the voltage divider circuit according to some example embodiments.

FIG. 7 is a circuit diagram illustrating a digitizer circuit according to some example embodiments.

FIG. 8 is a circuit diagram illustrating an inverter circuit according to some example embodiments.

FIG. 9 is a circuit diagram illustrating the inverter circuit according to some example embodiments.

FIG. 10 is a circuit diagram illustrating a protection circuit according to some example embodiments.

FIG. 11 is a circuit diagram illustrating a power semiconductor device according to some example embodiments.

FIG. 12 is a circuit diagram illustrating the power semiconductor device according to some example embodiments.

FIG. 13 is a plan view illustrating a portion of the power semiconductor device according to some example embodiments.

FIG. 14 is a cross-sectional view taken along line A-A′ of FIG. 13.

FIG. 15 is a cross-sectional view taken along line B-B′ of FIG. 13.

FIG. 16 is a cross-sectional view taken along line C-C′ of FIG. 13.

FIG. 17 is a cross-sectional view taken along line D-D′ of FIG. 13.

### DETAILED DESCRIPTION OF VARIOUS EMBODIMENTS

In the following detailed description, only some example embodiments of have been shown and described, simply by way of illustration. As those of ordinary skill in the art may realize, the described example embodiments may be modified in various different ways, all without departing from the spirit or scope of the present disclosure. Accordingly, the drawings and description are to be regarded as illustrative in nature and not restrictive. Like reference numerals designate like elements throughout the specification. In the flow charts described with reference to the drawings, the order of operations may be changed, and several operations may be combined, and an operation may be divided, and some operations may not be performed.

Portions unrelated to the description will be omitted in order to obviously describe the present disclosure, and similar components will be denoted by the same reference numerals throughout.

In addition, unless explicitly described to the contrary, the word “comprise”, and variations such as “comprises” or “comprising”, will be understood to imply the inclusion of stated elements but not the exclusion of any other elements.

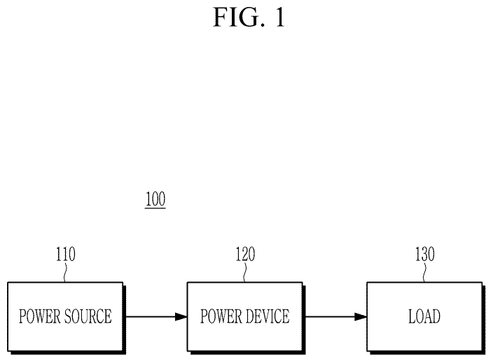

FIG. 1 is a block diagram schematically illustrating a power semiconductor system according to some example embodiments.

Referring to FIG. 1, a power semiconductor system 100 is or includes a system that uses power to operate, and may include, for example, one or more of transportation fields such as one or more of electric vehicles, railways, and electric trams, renewable energy systems such one or more of as solar power generation and wind power generation, mobile devices, or household electronic devices, etc. The power semiconductor system 100 may include a power source 110, a power device 120, and a load 130.

The power source 110 may supply power. The power source 110 may be a DC power source and/or an AC power source, but may include various types of power sources. In some example embodiments, the power source 110 may be a multi-phase alternator.

The power device 120 may transfer power from the power source 110 to the load 130. The power device 120 may transfer power to the load 130 and/or may perform power conversion through switching of a switching device. The power device 120 may include at least one component for converting, controlling, or dividing power. As an example, the power device 120 may include components such as one or more of an inverter, a converter, a power management IC (PMIC), and/or a power distribution unit (PDU). Components (e.g., one or more of inverter, converter, PMIC, PDU) included in the power device 120 may include various individual semiconductor devices therein to perform the function of converting, controlling, or dividing power. For example, the power device 120 may include individual semiconductor devices such as a transistor, such as one or more of an IGBT or MOSFET, a diode, or a thyristor.

In some example embodiments, the power device 120 may include power semiconductor devices that perform the switching operation. For example, the power device 120 may control an on/off operation of the power semiconductor devices to control or convert the supplied power.

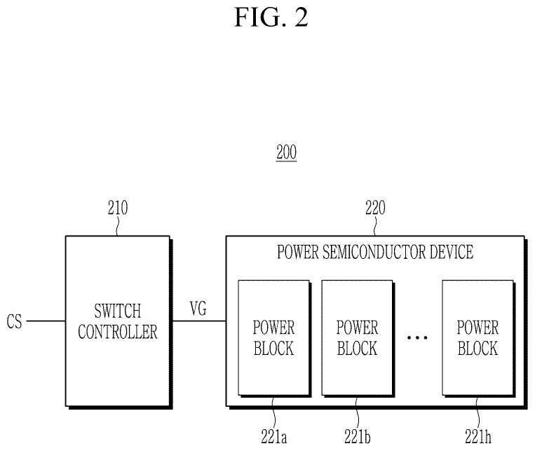

FIG. 2 is a block diagram illustrating a power device according to some example embodiments.

Referring to FIG. 2, the power device 200 may include a switch controller 210 and a power semiconductor device 220. The switch controller 210 may control the power semiconductor device 220. In some example embodiments, the switch controller 210 may receive a control signal CS and output a gate signal VG based on the control signal CS. The control signal CS may be input from inside and/or from outside the power device 200. For example, the control signal CS may be or be included in a signal output from a microprocessor such as a one or more of a central processing unit (CPU) chip, a graphic processing unit (GPU) chip, or an application processor (AP) chip. The control signal CS may be output from an integrated circuit (IC) included in the power device 200. In some example embodiments, the control signal CS may include a pulse width modulation (PWM) signal. The switch controller 210 may generate a gate signal VG having a targeted size or waveform based on information included in the control signal CS and output the generated gate signal VG to the outside. The information included in the control signal CS may be or may included, for example, a duty ratio of the PWM signal.

The gate signal VG may be a signal for controlling discrete semiconductor devices included in the power semiconductor device 220. In some cases, the gate signal VG may be or may include an electrical signal provided to a terminal of an individual semiconductor device included in the power semiconductor device 220.

In some example embodiments, the gate signal VG may have a larger value than the control signal CS.

For example, when the gate signal VG and the control signal CS are voltage signals, a voltage range (e.g., an absolute value) of the gate signal VG may be larger than that of the control signal CS. The switch controller 210 may convert the electrical signal received from the outside into an appropriate signal for controlling the individual semiconductor devices included in the power semiconductor device 220, and provide the converted electrical signal to the power semiconductor device 220.

In some example embodiments, the switch controller 210 may operate as a signal amplifier to process fast on/off switching of individual semiconductor devices included in the power semiconductor device 220.

The power semiconductor device 220 may include power blocks 222a, 221b, . . . , 221h. The power blocks 222a, 221b, . . . , 221h may be or include individual semiconductor devices that perform one unit function, or may be or include a set of individual semiconductor devices and/or passive devices configured to perform one unit function.

The power blocks 222a, 221b, . . . , 221h may be individual semiconductor devices that perform one unit function, and/or may be a set of individual semiconductor devices and/or passive devices configured to perform one unit function. Each of the power blocks 222a, 221b, . . . , 221h may perform the same, or different, unit function. One unit function may be, for example, a switching operation or a rectification operation. However, the functions performed by each power block 222a, 221b, . . . , 221h are not limited to the switching and rectification operations. For example, each of the power blocks 222a, 221b, . . . , 221h may be designed to perform not only the switching operation and rectification operations, but also various operations performed by various known individual semiconductor devices. The power blocks 222a, 221b, . . . , 221h are included in the power semiconductor device 220, and may perform the function of converting and/or controlling power like then inverter, the converter, the PMIC, etc., together with other power blocks 222a, 2221, . . . , 221h in the power semiconductor device 220.

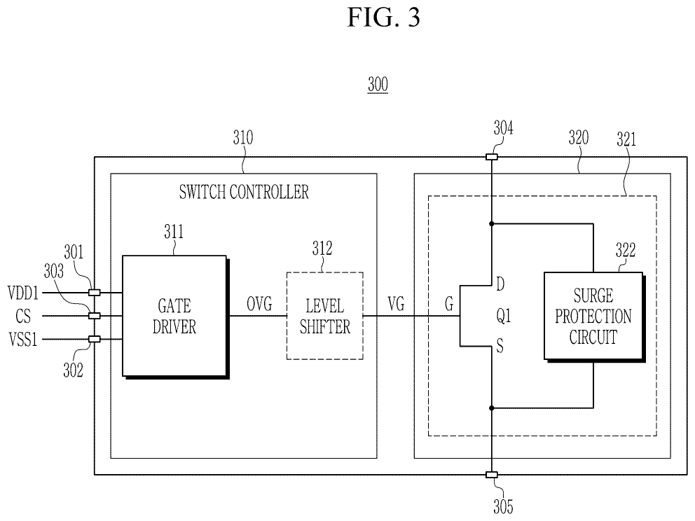

FIG. 3 is a block diagram illustrating in detail the power device according to some example embodiments.

Referring to FIG. 3, a power device 300 may include terminals 301, 302, and 303 for receiving signals provided to a switch controller 310, and load terminals 304 and 305 corresponding to a drain D and source S of a high electron mobility transistor Q1.

The power device 300 may include the switch controller 310 and a power block 320. The switch controller 310 may be connected to the power block 320. The switch controller 310 may be connected to the terminals 301, 302, and 303, and the power block 320 may be connected to the load terminals 304 and 305. For convenience of description, one power block 320 is illustrated in FIG. 3, but one switch controller 310 may be connected to the plurality of power blocks 320.

The switch controller 310 may receive a first driving voltage VDD1, a second driving voltage VSS1, and the control signal CS, and may output the gate signal VG based on the first driving voltage VDD1, the second driving voltage VSS1, and the control signal CS. The switch controller 310 may include a gate driver 311. In some example embodiments, the switch controller 310 may further include a level shifter 312; however, example embodiments are not limited thereto.

The gate driver 311 may generate a first gate signal OVG based on the control signal CS received from the outside. The first gate signal OVG may be or may include a signal for controlling the output of the gate signal VG output from the amplifier 22. The gate driver 311 may generate a raw gate signal OVG based on the control signal CS and then provide the generated raw gate signal OVG to the level shifter 312.

The level shifter 312 may level shift the raw gate signal OVG received from the gate driver 311 and may output the gate signal VG to the outside. Since the signal directly output from an external microprocessor or an internal integrated circuit, such as the control signal CS illustrated in FIG. 3, has relatively small power, it may not be sufficient to drive high-power devices such as the power semiconductor devices. The switch controller 310 according to various example embodiments may receive the control signal CS, which is the low-power input signal, and then, may output the high-power gate signal VG to the outside through the level shifter 312 based on the received control signal CS. In some example embodiments, the level shifter 312 may output to the outside the gate signal VG at a level that turns on or turns off the switching device included in the power semiconductor device 220, based on the raw gate signal OVG.

The power block 320 may include a substrate 321 on which a high electron mobility transistor Q1 is positioned. In some example embodiments, the substrate 321 may be or may include a gallium-nitride (GaN) die or GaN substrate.

In FIG. 3, the switch controller 310 is illustrated not disposed on the substrate 321, but some components within the switch controller 310 may be disposed on the substrate 321; example embodiments are not limited thereto.

The power block 320 may include a high electron mobility transistor Q1 and a surge protection circuit 322. The high electron mobility transistor Q1 may be or may include a switching device included in any one of the power blocks 222a, 2221, . . . , 221h described with reference to FIG. 2. The high electron mobility transistor Q1 may be connected between the load terminals 304 and 305. In some example embodiments, the drain D of the high electron mobility transistor Q1 may be connected to the load terminal 304, and the source S of the high electron mobility transistor Q1 may be connected to the load terminal 305. As illustrated in FIG. 3, other active devices and/or passive devices may further be positioned between the drain D of the high electron mobility transistor Q1 and the load terminal 304 and/or the source S of the high electron mobility transistor Q1 and the load terminal 305.

In some example embodiments, the load terminal 304 may be supplied with a power voltage from a voltage source. For example, the power voltage may have a voltage level of about 40V to about 1000V. The load terminal 305 may have a voltage level lower than (lower in absolute value than) the power voltage. For example, the load terminal 305 may be grounded. However, example embodiments are not limited thereto, and a voltage having a negative voltage level or a positive voltage level lower than that of the load terminal 304 may be supplied to the load terminal 305.

The gate G of the high electron mobility transistor Q1 may be connected to the output terminal of the switch controller 310. The high electron mobility transistor Q1 may receive a gate signal VG from the output terminal of the switch controller 310. The high electron mobility transistor Q1 may be turned on or off based on the level of the gate signal VG provided from the switch controller 310. For example, when a potential difference between the gate signal VG and the drain D of the high electron mobility transistor Q1 has a level equal to or higher than a threshold voltage of the high electron mobility transistor Q1, the high electron mobility transistor Q1 may stay or may be turned on. For example, when the potential difference between the gate signal VG and the drain D of the high electron mobility transistor Q1 has a level lower than the threshold voltage of the high electron mobility transistor Q1, the high electron mobility transistor Q1 may stay or may be turned off.

When a surge occurs in the power device 300, the surge protection circuit 322 may prevent or reduce the likelihood of and/or the impact from the power semiconductor system (100 in FIG. 1) including the high electron mobility transistor Q1 and the power device 300 from being damaged, thus improving the performance of the power device 300. A surge that instantly increases the voltage applied to the high electron mobility transistor Q1 may occur due to one or more of electro-static discharge (ESD), lightning that occurs around the power semiconductor system 100, or the operation of other systems that use large power. In silicon Si and/or silicon-carbon (SiC) power semiconductor devices, avalanche breakdown occurs at a PN junction within the devices, so a drain voltage may not be higher than an avalanche breakdown voltage. However, a GaN power semiconductor device does not have avalanche resistance, so the damage to the device may occur during avalanche breakdown.

A GaN HEMT device may have resistance to ESD through inductor-capacitor (LC) resonance, as illustrated in Equation 1, rather than the avalanche breakdown. This was confirmed in an unclamped inductive switching (UIS) test to evaluate resistance to surge.

$${E}_{Surge} = \frac{{C}_{O S S}}{2} B {V}^{2} {E}_{Surge} = \frac{{C}_{O S S}}{2} B {V}^{2} \qquad ( Equation 1 )$$

Here, E_{surge} may be surge energy, BV may be breakdown voltage, and C_{OSS} may be output capacitance. In some cases, the GaN HEMT device with a relatively large output capacitance may have relatively large surge energy and therefore, has relatively good resistance to surge.

The surge protection circuit 322 may increase the output capacitance of the high electron mobility transistor Q1 when the surge occurs. The surge protection circuit 322 may increase the surge energy E_{surge} by increasing the output capacitance, but in this case, a switching loss due to capacitance may increase as the operating speed increases. In some example embodiments, the surge protection circuit 322 may connect an output capacitor between the drain D and the source S when the surge occurs. The surge protection circuit 322 may disconnect the output capacitor between the drain D and the source S during normal operation in which no surge occurs.

The surge protection circuit 322 may operate based on the voltage between the drain D and the source S. For example, the surge protection circuit 322 may connect the output capacitor between the drain D and the source S when the voltage between the drain D and the source S exceeds a threshold value, e.g., exceeds a dynamically determined (or, alternatively, a predetermined) threshold value. The surge protection circuit 322 may disconnect the output capacitor between the drain D and the source S when the voltage between the drain D and the source S is smaller than and equal to the threshold value.

The surge protection circuit 322 may operate based on a voltage dividing the voltage between the drain D and the source S. For example, the surge protection circuit 322 may connect the output capacitor between the drain D and the source S when the voltage dividing the voltage between the drain D and the source S exceeds the threshold. The surge protection circuit 322 may disconnect the output capacitor between the drain D and the source S when the voltage dividing the voltage between the drain D and the source S is smaller than or equal to the threshold value.

In some example embodiments, there may be a surge protection circuit 322 for at least as many as the number of high electron mobility transistors Q1 included in the power device 300. For example, the power device 300 includes the plurality of high electron mobility transistors Q1 and there may be a surge protection circuit 322 connected between the drain D and source S of each of the plurality of high electron mobility transistors Q1. However, example embodiments are not limited thereto, and the power device 300 may have one surge protection circuit 322 per power block. In some cases, each of the power blocks 222a, 2221, . . . , 221h described with reference to FIG. 2 may include the plurality of high electron mobility transistors Q1, and the plurality of high electron mobility transistors Q1 included in each of the power blocks 222a, 2221, . . . , 221h . . . , 221h may be connected in common to one surge protection circuit 322. The surge protection circuit 322 may increase the output capacitance of the plurality of high electron mobility transistors Q1 when the surge occurs in at least one of the plurality of high electron mobility transistors Q1.

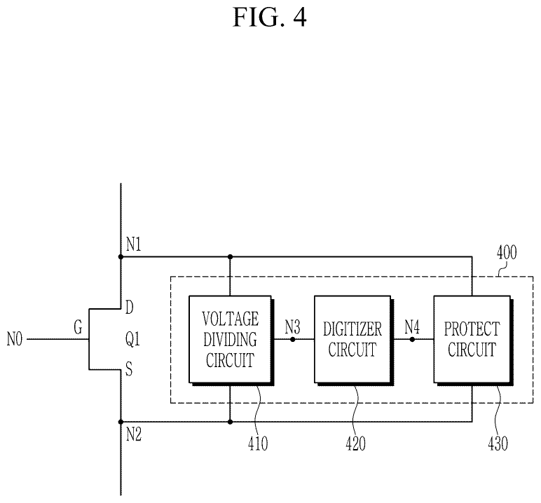

FIG. 4 is a block diagram illustrating a power semiconductor device according to some example embodiments.

Referring to FIG. 4, the gate G of the high electron mobility transistor Q1 may be connected to a node NO, the drain D may be connected to a node N1, and the source S may be connected to a node N2

A surge protection circuit 400 may be connected to both terminals of the high electron mobility transistor Q1. The surge protection circuit 400 may be connected between the node N1 and the node N2.

The surge protection circuit 400 may include a voltage divider circuit 410, a digitizer circuit 420, and a protection circuit 430.

The voltage divider circuit 410 may divide the drain-source voltage of the high electron mobility transistor Q1 and output the divided voltage to the digitizer circuit 420. The voltage divider circuit 410 may be connected between the node N1 and the node N2, and may output the divided voltage to the node N3.

The digitizer circuit 420 may be connected to the voltage divider circuit 410 at the node N3 and to the protection circuit 430 at the node N4. The digitizer circuit 420 may receive the voltage divided by the voltage divider circuit 410 at the node N3 and may output a first voltage or a second voltage lower than (lower in absolute value than) the first voltage based on the divided voltage. In some example embodiments, the digitizer circuit 420 may output the first voltage when the divided voltage is higher than (higher in absolute value than) the threshold voltage, and output the second voltage when the divided voltage is smaller than or equal to (smaller or equal to in absolute value than) the threshold voltage.

The protection circuit 430 may be connected to both terminals of the high electron mobility transistor Q1 between the node N1 and the node N2, and may be connected to the digitizer circuit 420 at the node N4. The protection circuit 430 may connect or disconnect a capacitor between the node N1 and the node N2 based on the voltage output by the digitizer circuit 420.

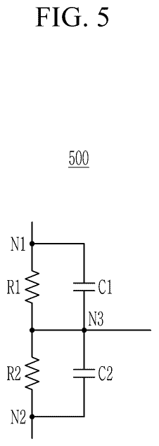

FIG. 5 is a circuit diagram illustrating the voltage divider circuit according to some example embodiments.

Referring to FIG. 5, the voltage divider circuit 500 may include a plurality of resistors R1 and R2 and a plurality of capacitors C1 and C2 connected in series between the node N1 and the node N2. A voltage divided according to a resistance ratio of the plurality of resistors R1 and R2 may be output to the node N3.

In some example embodiments, the voltage divider circuit 500 may include only the plurality of resistors R1 and R2 connected in series between the node N1 and the node N2. When used in the power device where the voltage difference between the node N1 and the node N2 is relatively small, the voltage divider circuit 500 may include only the plurality of resistors R1 and R2 connected in series.

In some example embodiments, the voltage divider circuit 500 may include only the plurality of capacitors C1 and C2 connected in series between the node N1 and the node N2. Since it may be difficult to form a resistor with a high resistance value in or on the GaN substrate upon which the HEMT element is positioned, when used in the power device where the voltage difference between node N1 and node N2 is large, instead of the plurality of resistors R1 and R2, the GaN substrate may include the plurality of capacitors C1 and C2 connected in series between the node N1 and the node N2.

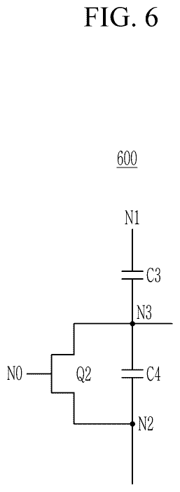

FIG. 6 is a circuit diagram illustrating the voltage dividing circuit according to some example embodiments.

Referring to FIG. 6, a voltage divider circuit 600 may include the plurality of capacitors C1 and C2 connected in series between the node N1 and the node N2 and a transistor Q2 connected between the node N3 and the node N2. A voltage according to a capacity ratio of the plurality of capacitors C3 and C4 may be output to the node N3.

When the plurality of capacitors C1 and C2 are connected in series between the node N1 and the node N2, the node N3 may be in a floating state. Therefore, in order to sink charges stored in the plurality of capacitors C1 and C2, the transistor Q2 may be connected between the node N3 and the node N2. A gate of the transistor Q2 may be connected to the node NO. The transistor Q2 may sink the charge stored in the plurality of capacitors C3 and C4 when the high electron mobility transistor Q1 is turned on.

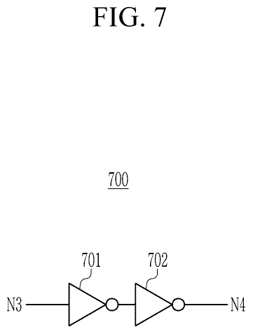

FIG. 7 is a circuit diagram illustrating a digitizer circuit according to some example embodiments.

Referring to FIG. 7, a digitizer circuit 700 may include a plurality of inverter circuits 701 and 702, e.g., an even number of inverter circuits, connected in series between the node N3 and the node N4. The digitizer circuit 700 may output the first voltage or the second voltage to the node N4 depending on the magnitude of the voltage input from the node N3.

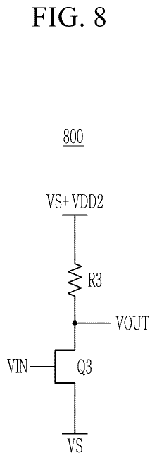

FIG. 8 is a circuit diagram illustrating an inverter circuit (e.g., an NMOS inverter circuit) according to some example embodiments.

Referring to FIG. 8, an inverter circuit 800 is connected between an output terminal VOUT and a second voltage VS, and may include a transistor Q3 including a gate connected to an input terminal VIN and a resistor R3 connected between a first voltage VS+VDD2 and the output terminal VOUT. When a voltage smaller than the threshold voltage of the transistor Q3 is input to the input terminal VIN, the inverter circuit 800 outputs the first voltage VS+VDD2 to the output terminal VOUT and when a voltage higher than or equal to the threshold value of the transistor Q3 is input to the input terminal VIN, the second voltage VS may be output to the output terminal VOUT.

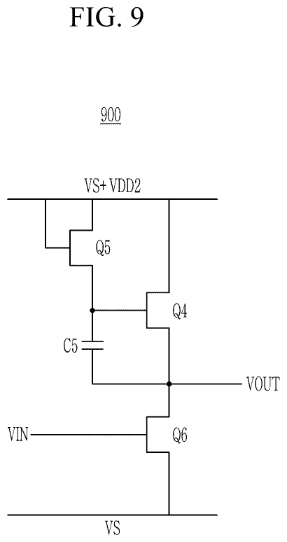

FIG. 9 is a circuit diagram illustrating an inverter circuit according to some example embodiments.

Referring to FIG. 9, an inverter circuit 900 may include a transistor Q4 connected between the first voltage VS+VDD2 and the output terminal VOUT, a transistor Q5 connected between the first voltage VS+VDD2 and a gate of the transistor Q4 and including the gate connected to the first voltage VS+VDD2, and a transistor Q6 connected between the output terminal VOUT and the second voltage VS and including a gate connected to the input terminal VIN, and a capacitor C5 connected between the gate of the transistor Q4 and the output terminal VOUT. When a voltage smaller than the threshold voltage of the transistor Q6 is input to the input terminal VIN, the inverter circuit 900 outputs the first voltage VS+VDD2 to the output terminal VOUT and when a voltage higher than or equal to the threshold value of the transistor Q6 is input to the input terminal VIN, the second voltage VS may be output to the output terminal VOUT.

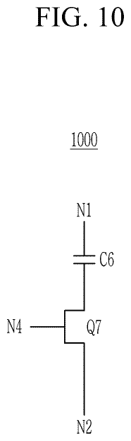

FIG. 10 is a circuit diagram illustrating a protection circuit according to some example embodiments.

Referring to FIG. 10, a protection circuit 1000 may include the capacitor C6 and a transistor Q7 connected in series between the node N1 and the node N2. A gate of the transistor Q7 may be connected to the node N4. When the first voltage VS+VDD2 is input to the node N4, the transistor Q7 may be turned on. Then, the capacitor C6 may be electrically connected between the node N1 and the node N2. When the second voltage VS is input to the node N4, the transistor Q7 may be turned off.

When the power device operates normally, the transistor Q7 is turned off, so the output capacitance does not increase, and when a surge occurs and the drain voltage of the high electron mobility transistor Q1 increases compared to the normal operating voltage, the transistor Q7 may be turned on and the output capacitance may increase. Therefore, when the surge occurs, the C_{OSS} of Equation 1 increases, so the surge energy E_{surge} may increase.

Example embodiments are not limited to the above. In some cases, example embodiments may include one or more features described above with reference to one or more of FIGS. 5-10, and may also include one or more other features described above with reference to FIGS. 5-10. Alternatively or additionally, in some cases, one of power blocks 221a, 221b, . . . , 22h may include one or more of the example embodiments described with reference to FIGS. 5-10, and another of the power blocks 22a, 22b, . . . , 22h may include one or more others of the example embodiments described with reference to FIGS. 5-10. Further, transistors included in, e.g., FIGS. 8, 9, and 10 may or may not be NMOS transistors, and may or may not be high-electron mobility transistors and may in some cases be Si and/or SiC transistors; example embodiments are not limited thereto

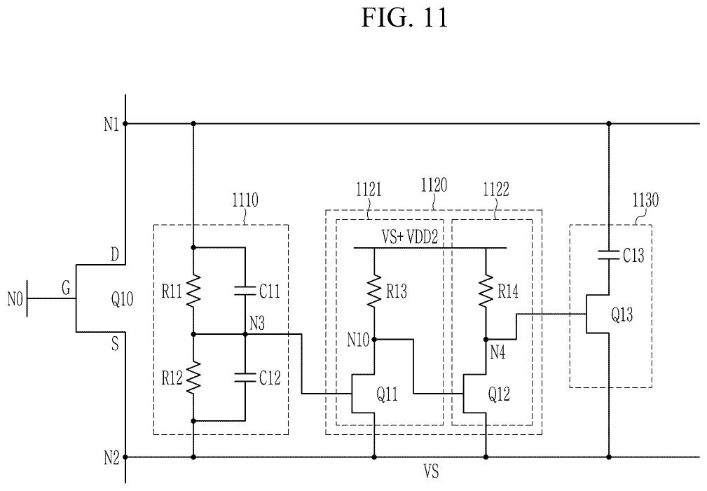

FIG. 11 is a circuit diagram illustrating a power semiconductor device according to some example embodiments.

Referring to FIG. 11, a drain D of a high electron mobility transistor Q10 may be connected to the node N1, a source S of the high electron mobility transistor Q10 may be connected to the node N2, and a gate G of the high electron mobility transistor Q10 may be connected to the node NO to which the gate signal is applied.

A voltage divider circuit 1110 may be connected between the node N1 and the node N2. The voltage divider circuit 1110 may include a plurality of resistors R11 and R12 and a plurality of capacitors C11 and C12 connected in series between the node N1 and the node N2.

A digitizer circuit 1120 may include two inverter circuits 1121 and 1122 connected in series between the node N3 and the node N4.

The inverter circuit 1121 may include a transistor Q11 connected between the output terminal N10 and the second voltage VS and including a gate connected to the input terminal N3, and a resistor R13 connected between the first voltage VS+VDD2 and the output terminal N10.

The inverter circuit 1122 may include a transistor Q12 connected between the output terminal N4 and the second voltage VS and including a gate connected to the input terminal N10, and a resistor R14 connected between the first voltage VS+VDD2 and the output terminal N4.

The protection circuit 1130 may include a capacitor C13 and a transistor Q13 connected in series between the node N1 and the node N2. Any one or more of the transistors Q11, Q12, and Q13 may or may not be high electron mobility transistors; example embodiments are not limited thereto.

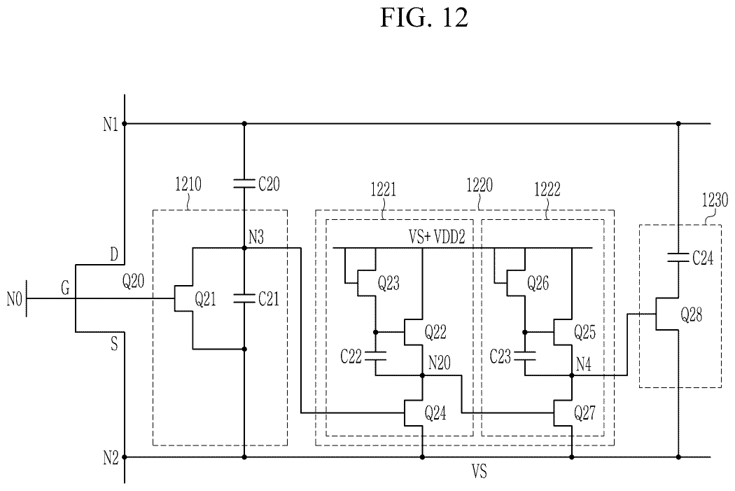

FIG. 12 is a circuit diagram illustrating the power semiconductor device according to some example embodiments.

Referring to FIG. 12, a drain D of a high electron mobility transistor Q20 may be connected to the node N1, a source S of the high electron mobility transistor Q20 may be connected to the node N2, and a gate G of the high electron mobility transistor Q20 may be connected to the node NO to which the gate signal is applied.

A voltage divider circuit 1210 may include the plurality of capacitors C20 and C21 connected in series between the node N1 and the node N2 and a transistor Q21 connected between the node N3 and the node N2. A voltage according to a capacity ratio of the plurality of capacitors C20 and C21 may be output to the node N3. A gate of the transistor Q21 may be connected to the node NO.

A digitizer circuit 1220 may include two inverter circuits 1221 and 1222 connected in series between the node N3 and the node N4.

The inverter circuit 1221 may include a transistor Q22 connected between the first voltage VS+VDD2 and an output terminal N20, a transistor Q23 connected between the first voltage VS+VDD2 and a gate of the transistor Q22, a transistor Q24 connected between the output terminal N20 and the second voltage VS and including a gate connected to the input terminal N3, and a capacitor C22 connected between the gate of the transistor Q22 and the output terminal N20.

The inverter circuit 1222 may include a transistor Q25 connected between the first voltage VS+VDD2 and the output terminal N4, a transistor Q26 connected between the first voltage VS+VDD2 and a gate of the transistor Q25, a transistor Q27 connected between the output terminal N4 and the second voltage VS and including a gate connected to the input terminal N20, and a capacitor C23 connected between the gate of the transistor Q25 and the output terminal N4.

The protection circuit 1230 may include a capacitor C24 and a transistor Q28 connected in series between the node N1 and the node N2. Any one or more of the transistors Q21, Q22, Q23, Q24, Q25, Q26, Q27, or Q18 may or may not be high electron mobility transistors; example embodiments are not limited thereto.

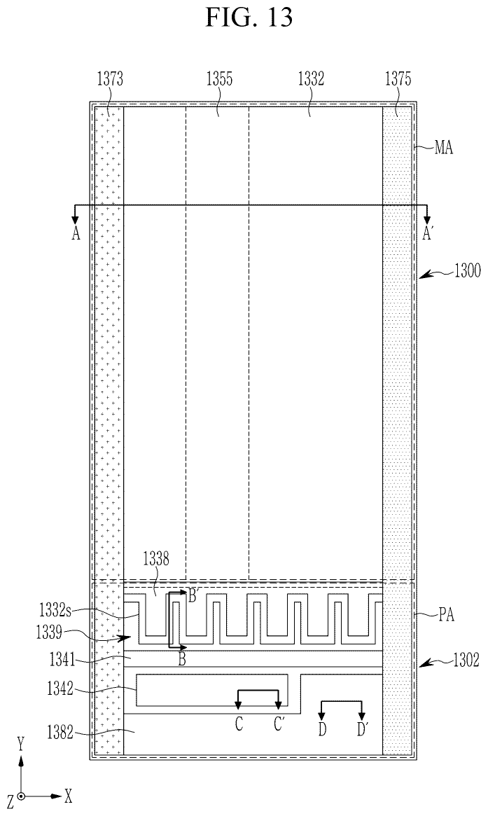

FIG. 13 is a plan view illustrating a portion of the power semiconductor device according to some example embodiments.

Referring to FIG. 13, a peripheral circuit area PA of the power semiconductor device according to some example embodiments may be positioned spaced apart from a device area MA. For example, the peripheral circuit area PA may be positioned to be spaced apart from the device area MA in a second direction (Y direction), but is not limited thereto. For example, the peripheral circuit area PA may be positioned spaced apart from the device area MA in a first direction (X direction), or may surround a side surface of the device area MA. Various other changes are possible. In some example embodiments, a separation structure 1360 may be positioned between the peripheral circuit area PA and the device area MA, but is not limited thereto.

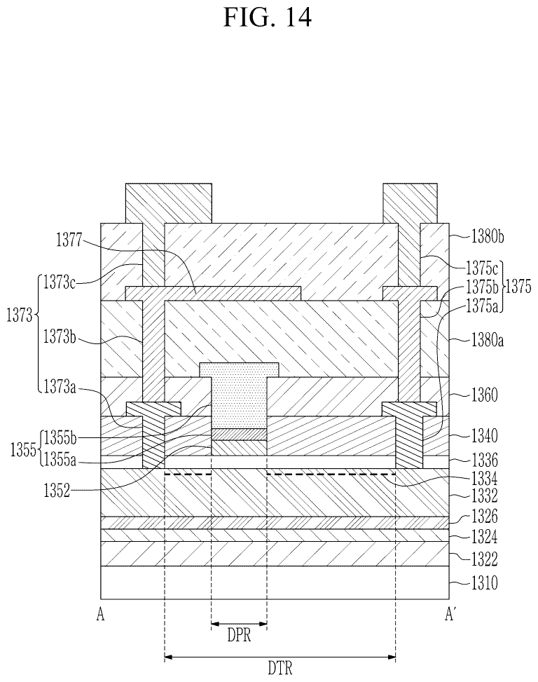

FIG. 14 is a cross-sectional view taken along line A-A′ of FIG. 13.

Referring to FIGS. 13 and 14 together, a transistor 1300 of the power semiconductor device according to some example embodiments may include a channel layer 1332, a barrier layer 1336 positioned on the channel layer 1332, a gate semiconductor layer 1352 positioned on the barrier layer 1336, a protective layer 1340 positioned above the barrier layer 1336, and a source electrode 1373 and a drain electrode 1375 spaced apart from each other on the channel layer 1332.

The channel layer 1332 is or includes a layer that forms a channel between the source electrode 1373 and the drain electrode 1375, and a 2 dimensional electron gas (2 DEG) 1334 may be positioned inside the channel layer 1332. The two-dimensional electron gas 1334 is or includes a charge transport model used in solid state physics, and may move freely in two dimensions (e.g., x-y plane direction), but may refer to a group of electrons that are tightly bound within two dimensions without moving in another dimension (e.g., z-direction). For example, the two-dimensional electron gas 1334 may exist in a two-dimensional paper-like form within a three-dimensional space. The two-dimensional electron gas 1334 mainly appears in a semiconductor heterojunction structure, and may occur at an interface between the channel layer 1332 and the barrier layer 1336 in the power semiconductor device according to some example embodiments. For example, the two-dimensional electron gas 1334 may be generated in a portion of the channel layer 1332 adjacent to the barrier layer 1336.

The channel layer 1332 may include one or more materials selected from Group III-V materials, such as nitrides including Al, Ga, In, B, or a combination thereof. The channel layer 1332 may be made of a single layer or multiple layers. The channel layer 1332 may be AlxInyGa1-x-yN (0≤x≤1, 0≤y≤1, x+y≤1). For example, the channel layer 1332 may include AlN, GaN, InN, InGaN, AlGaN, AlInN, AlInGaN, or a combination thereof. The channel layer 1332 may be a layer doped with impurities or a layer undoped with impurities. The thickness of the channel layer 1332 may be about several hundred nm or less, e.g., about several hundred angstroms or less.

The channel layer 1332 may be positioned on a substrate 1310, and a buffer layer 1322, a superlattice layer 1324, a high-resistance layer 1326, etc., may be positioned between the substrate 1310 and the channel layer 1332. The substrate 1310, the buffer layer 1322, and the superlattice layer 1324 are layers necessary or used to form the channel layer 1332, and may be omitted in some cases. For example, when a substrate made of GaN is used as the channel layer 1332, at least one of the substrate 1310, the buffer layer 1322, and the superlattice layer 1324 may be omitted. Considering that the price of the substrate made of GaN is relatively high, the channel layer 1332 including GaN may be grown using the substrate 1310 made of Si. In this case, as a lattice structure of Si and a lattice structure of GaN are different, it may not be easy to grow the channel layer 1332 directly on the substrate 1310. Accordingly, the buffer layer 1322 and the superlattice layer 1324 may be first grown on the substrate 1310, and then the channel layer 1332 may be grown on the superlattice layer 1324. Alternatively or additionally, at least one of the substrate 1310, the buffer layer 1322, and the superlattice layer 1324 may be removed from the final structure of the semiconductor device after being used in the manufacturing process.

The substrate 1310 may include a semiconductor material. For example, the substrate 1310 may include sapphire, Si, SiC, AlN, GaN, or a combination thereof. The substrate 1310 may be a silicon on insulator (SOI) substrate. However, the material of the substrate 1310 is not limited thereto, and any commonly used substrate may be applied. In some cases, the substrate 1310 may include an insulating material. For example, in addition to the channel layer 1332, several layers may be first formed on a semiconductor substrate, and then the semiconductor substrate may be removed and replaced with an insulating substrate.

The buffer layer 1322 may be positioned on the substrate 1310. Although not illustrated, a seed layer may be further positioned between the substrate 1310 and the buffer layer 1322. The seed layer may be positioned directly above the substrate 1310. However, it is not limited thereto, and another layer such as another predetermined layer may be further positioned between the substrate 1310 and the seed layer. The seed layer is a layer that serves as a seed for growing the buffer layer 1322, and may be made of a crystal lattice structure that becomes the seed of the buffer layer 1322. For example, the seed layer may include one or more materials selected from Group III-V materials, such as nitrides including Al, Ga, In, B, or a combination thereof. The seed layer may be AlxInyGa1-x-yN (0≤x≤1, 0≤y≤1, x+y≤1). For example, the seed layer may include AlN, GaN, InN, InGaN, AlGaN, AlInN, AlInGaN, or a combination thereof, but is not limited thereto. The buffer layer 1322 may be positioned directly above the seed layer. However, example embodiments are not limited thereto, and another layer or predetermined layer may be further positioned between the seed layer and the buffer layer 1322.

The buffer layer 1322 may be positioned between the substrate 110 and the superlattice layer 124. The buffer layer 1320 may be a layer to alleviate a difference in lattice constant and thermal expansion coefficient between the seed layer 1321 and the channel layer 1332, or to prevent a leakage current from flowing through the channel layer 1332. The buffer layer 1322 may include one or more materials selected from Group III-V materials, for example, nitrides including at least one of Al, Ga, In, and B. The buffer layer 1322 may include one or more materials selected from Group III-V materials, such as nitrides including Al, Ga, In, B, or a combination thereof. The buffer layer 1322 may be AlxInyGa1-x-yN (0≤x≤1, 0≤y≤1, x+y≤1). For example, the buffer layer 1322 may include AlN, GaN, InN, InGaN, AlGaN, AlInN, AlInGaN, or a combination thereof. The buffer layer 1322 may be made of a single layer or multiple layers.

The superlattice layer 124 may be positioned on the buffer layer 122. The superlattice layer 124 may be positioned directly above the buffer layer 122. However, example embodiments are not limited thereto, and another layer such as another predetermined layer may be further positioned between the seed layer 1321 and the superlattice layer 1324. The superlattice layer 1324 is or includes a layer for alleviating the difference in lattice constant and thermal expansion coefficient between the substrate 1310 and the channel layer 1332 to alleviate the tensile stress and compressive stress generated between the substrate 1310 and the channel layer 1332, and alleviate or improves upon the stress between the overall layers formed by growth in the final structure of the power semiconductor device according to some example embodiments. The superlattice layer 1324 may include one or more materials selected from Group III-V materials, such as nitrides including Al, Ga, In, B, or a combination thereof. The superlattice layer 1324 may be AlxInyGa1-x-yN (0≤x≤1, 0≤y≤1, x+y≤1). For example, the superlattice layer 1324 may include AlN, GaN, InN, InGaN, AlGaN, AlInN, AlInGaN, or a combination thereof.

In some example embodiments, the superlattice layer 1324 may be made of multiple layers in which layers including different materials are alternately stacked. For example, the superlattice layer 1324 may have a structure in which a layer made of AlGaN and a layer made of AlN are repeatedly stacked.

In some cases, AlGaN/AlN/AlGaN/AlN/AlGaN/AlN may be sequentially stacked to form the superlattice layer.

The number of AlGaN layers and GaN included in the superlattice layer 1324 may change in various ways, and the material included in the superlattice layer 1324 may change in various ways. As another example, the superlattice layer 1324 may have a structure in which a layer made of AlGaN and a layer made of GaN are repeatedly stacked. For example, AlGaN/GaN/AlGaN/GaN/AlGaN/GaN may be sequentially stacked to form the superlattice layer.

In some example embodiments, when the superlattice layer 1324 includes GaN, InN, AlGaN, AlInN, InGaN, AlN, AlInGaN, or a combination thereof, the superlattice layer 1324 may have n-type semiconductor characteristics in which the electron concentration is greater than the hole concentration, but is not limited thereto.

The high-resistance layer 1326 may be positioned on the superlattice layer 1324. The high-resistance layer 1326 may be positioned directly above the superlattice layer 1324. However, example embodiments are not limited thereto, and another predetermined layer may be further positioned between the superlattice layer 1324 and the high-resistance layer 1326. The high-resistance layer 1326 may be positioned between the superlattice layer 1324 and the channel layer 1332. The high-resistance layer 1326 is or includes a layer for preventing or reducing leakage current from flowing through the channel layer 1332 to prevent the power semiconductor device according to some example embodiments from being deteriorated. The high-resistance layer 1326 may be made of a low-conductivity material to electrically insulate between the substrate 1310 and the channel layer 1332. The high-resistance layer may include one or more materials selected from group III-V materials, such as nitrides including Al, Ga, In, B, or combinations thereof. The high-resistance layer 1326 may be AlxInyGa1-x-yN (0≤x≤1, 0≤y≤1, x+y≤1). For example, the high-resistance layer 1326 may include AlN, GaN, InN, InGaN, AlGaN, AlInN, AlInGaN, or a combination thereof. The high-resistance layer 1326 may be made of a single layer or multiple layers. In some example embodiments, when the high-resistance layer 1326 includes GaN, InN, AlGaN, AlInN, InGaN, AlN, AlInGaN, or a combination thereof, the high-resistance layer 1326 may have n-type semiconductor characteristics in which the electron concentration is greater than the hole concentration, but is not limited thereto.

The barrier layer 1336 may be positioned above channel layer 1332. The barrier layer 1336 may be positioned directly above channel layer 1332. However, example embodiments are not limited thereto, and another layer such as another predetermined layer may be further positioned between the channel layer 1332 and the barrier layer 1336. An area of the channel layer 1332 that overlaps the barrier layer 1336 may be a drift areas DTR. The drift area DTR may be positioned between the source electrode 173 and the drain electrode 175. When a potential difference occurs between the source electrode 173 and the drain electrode 175, carriers may move in the drift area DTR. A semiconductor device according to some example embodiments may be turned on/off depending on whether a voltage is applied to the gate electrode 1355 and the magnitude of the voltage applied to the gate electrode 1355. When a voltage greater than the threshold voltage is applied to the gate electrode 1355 and the semiconductor device is turned on, the channel may be generated in a depletion area DPR. Accordingly, the movement of the carrier may occur in the drift areas DTR. When a voltage lower than the threshold voltage or no voltage is applied to the gate electrode 1355, a channel path may be blocked in the depletion area (DPR), so the carrier movement may not occur.

The barrier layer 1336 may include one or more materials selected from Group III-V materials, such as nitrides containing Al, Ga, In, B, or a combination thereof. The barrier layer 1336 may be AlxInyGa1-x-yN (0≤x≤1, 0≤y≤1, x+y≤1). The barrier layer 1336 may include GaN, InN, AlGaN, AlInN, InGaN, AlN, AlInGaN, a combination thereof, etc. An energy band gap of the barrier layer 1336 may be adjusted by a composition ratio of Al and/or In. The barrier layer 1336 may be doped with a predetermined impurity. In this case, the impurity doped into the barrier layer 1336 may be a p-type dopant that may provide holes. For example, the impurity doped into the barrier layer 1336 may be magnesium (Mg). By increasing or decreasing the impurity doping concentration of the barrier layer 1336, one or more electrical properties, such as one or more of the threshold voltage, on-resistance, etc., of the power semiconductor device according to some example embodiments may be adjusted.

The barrier layer 1336 may include a semiconductor material having different characteristics from the channel layer 1332. The barrier layer 1336 may be different from the channel layer 1332 in at least one of polarization characteristics, energy band gap, or lattice constant. For example, the barrier layer 1336 may include a material having a different energy band gap than the channel layer 1332. In this case, the barrier layer 1336 may have a higher energy band gap than the channel layer 1332 and may have a higher electrical polarization rate than the channel layer 1332. The two-dimensional electron gas 1334 may be induced in the channel layer 1332 with a relatively low electrical polarization rate by the barrier layer 1336. In this regard, the barrier layer 1336 may also be called a channel supply layer or a two-dimensional electron gas supply layer. The two-dimensional electron gas 1334 may be formed within the portion of the channel layer 1332 positioned below the interface between the channel layer 1332 and the barrier layer 1336. The two-dimensional electron gas 1334 may have very high electron mobility.

The barrier layer 1336 may be made of a single layer or multiple layers. When the barrier layer 1336 is made of multiple layers, the materials of each layer constituting the multiple layers may have different energy band gaps. In this case, various layers constituting the barrier layer 1336 may be arranged so that the energy band gap increases as the layers approach the channel layer 1332.

The gate electrode 1355 may be positioned on the barrier layer 1336. The gate electrode 1355 may overlap a portion of the barrier layer 1336 in a vertical direction (e.g., the thickness direction of the channel layer 1332). The gate electrode 1355 may overlap a portion of the drift area DTR of the channel layer 1332 in a vertical direction (e.g., the thickness direction of the channel layer 1332). The gate electrode 1355 may be positioned between the source electrode 1373 and the drain electrode 1375. The gate electrode 1355 may be spaced apart from the source electrode 1373 and the drain electrode 1375. For example, the gate electrode 1355 may be positioned closer to the source electrode 1373 than the drain electrode 1375. That is, a separation distance between the gate electrode 1355 and the source electrode 1373 may be smaller than that between the gate electrode 1355 and the drain electrode 1375, but is not limited thereto.

The gate electrode 1355 may include a conductive material. For example, the gate electrode 1355 may include metal, metal alloy, conductive metal nitride, metal silicide, doped semiconductor material, conductive metal oxide, conductive metal nitride, etc. For example, the gate electrode 1355 may be made of titanium nitride (TiN), tantalum carbide (TaC), tantalum nitride (TaN), titanium silicon nitride (TiSiN), tantalum silicon nitride (TaSiN), tantalum titanium nitride (TaTiN), or titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TIC), tantalum carbonitride (TaCN), tungsten (W), aluminum (Al), copper (Cu), cobalt (Co), titanium (Ti), tantalum (Ta), nickel (Ni), platinum (Pt), Nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof, but are not limited thereto. The gate electrode 1355 may be made of a single layer or multiple layers.

The gate semiconductor layer 1352 may be positioned between the barrier layer 1336 and the gate electrode 1355. That is, the gate semiconductor layer 1352 may be positioned on the barrier layer 1336, and the gate electrode 1355 may be positioned on the gate semiconductor layer 1352. The gate electrode 1355 may be in Schottky contact or ohmic contact with the gate semiconductor layer 1352. The gate semiconductor layer 1352 may overlap the gate electrode 1355 in a vertical direction (e.g., the thickness direction of the channel layer 1332). In this case, the gate semiconductor layer 1352 may completely overlap the gate electrode 1355 in a vertical direction (for example, the thickness direction of the channel layer 1332), and an upper surface of the gate semiconductor layer 1352 may be entirely covered by the gate electrode 1355. That is, the gate semiconductor layer 1352 may have substantially the same planar shape as the gate electrode 1355. However, example embodiments are not limited thereto, and the gate electrode 1355 may be positioned to cover at least a portion of the gate semiconductor layer 1352.

The gate semiconductor layer 1352 may be positioned between the source electrode 1373 and the drain electrode 1375. The gate semiconductor layer 1352 may be spaced apart from the source electrode 1373 and the drain electrode 1375. The gate semiconductor layer 1352 may be positioned closer to the source electrode 1373 than the drain electrode 1375. That is, the separation distance between the gate semiconductor layer 1352 and the source electrode 1373 may be smaller than that between the gate semiconductor layer 1352 and the drain electrode 1375, but is not limited thereto.

In some example embodiments, the gate semiconductor layer 1352 may overlap the gate electrode 1355 in the vertical direction (e.g., the thickness direction of the channel layer 1332). For example, the gate semiconductor layer 1352 may completely overlap the gate electrode 1355 in the vertical direction (e.g., the thickness direction of the channel layer 1332).

For example, a side surface of the gate semiconductor layer 1352 may be aligned with a side surface of the gate electrode 1355.

However, example embodiments are not limited thereto, and the gate semiconductor layer 1352 may partially overlap the gate electrode 1355.

The gate semiconductor layer 1352 may include one or more materials selected from Group III-V materials, such as nitrides containing Al, Ga, In, B, or a combination thereof. The gate semiconductor layer 1352 may be AlxInyGa1-x-yN (0≤x≤1, 0≤y≤1, x+y≤1). For example, the gate semiconductor layer 1352 may include AlN, GaN, InN, InGaN, AlGaN, AlInN, AlInGaN, or a combination thereof. The gate semiconductor layer 1352 may include a material having a different energy band gap than the barrier layer 1336. For example, the gate semiconductor layer 1352 may include GaN, and the barrier layer 1336 may include AlGaN. The gate semiconductor layer 1352 may be doped with a predetermined impurity. In this case, the impurity doped into the gate semiconductor layer 1352 may be a p-type dopant that may provide holes. For example, the gate semiconductor layer 1352 may include GaN doped with p-type impurities. For example, the gate semiconductor layer 1352 may be made of a p-GaN layer. However, example embodiments are not limited thereto, and the gate semiconductor layer 1352 may be a p-AlGaN layer. The impurity doped into the gate semiconductor layer 1352 may be magnesium (Mg). In this case, when a predetermined element adjacent to an impurity (for example, magnesium) doped in the gate semiconductor layer 1352 combines, the hole concentration in the gate semiconductor layer 1352 may be reduced, so the characteristics of the electric power semiconductor device may be degraded. The gate semiconductor layer 1352 may be made of a single layer or multiple layers.

The depletion area (DPR) may be formed in the channel layer 1332 by the gate semiconductor layer 1352. The depletion area DPR may be positioned within the drift area DTR and may have a narrower width than the drift area DTR. As the gate semiconductor layer 1352 having a different energy band gap from the barrier layer 1336 is positioned on the barrier layer 1336, the level of the energy band of the portion of the barrier layer 1336 that overlaps the gate semiconductor layer 1352 may increase. Accordingly, the depletion area (DPR) may be formed in the area of the channel layer 1332 that overlaps the gate semiconductor layer 1352. The depletion area DPR may be an area in the channel path of the channel layer 1332 where the two-dimensional electron gas 1334 is not formed or may have an area that has a lower electron concentration than the remaining area. For example, the depletion area (DPR) may refer to an area where the flow of the two-dimensional electron gas 1334 is interrupted within the drift areas DTR. As the depletion area (DPR) occurs, a current does not flow between the source electrode 1373 and the drain electrode 1375, and the channel path may be blocked. Accordingly, the power semiconductor device according to some example embodiments may have normally off characteristics.

For example, the power semiconductor device according to some example embodiments may be a normally off high electron mobility transistor (HEMT). As illustrated in FIG. 14, in a normal state in which no voltage is applied to the gate electrode 1355, the depletion area (DPR) exists, and the power semiconductor device according to some example embodiments may be in an off state. When a voltage greater than the threshold voltage is applied to the gate electrode 1355, the depletion area (DPR) disappears, and the two-dimensional electron gas 1334 may be connected without being disconnected within the drift areas DTR. For example, the two-dimensional electron gas 1334 may be formed throughout the channel path between the source electrode 1373 and the drain electrode 1375, and the power semiconductor device according to some example embodiments may be in an on state. In summary, the power semiconductor device according to various example embodiments may include semiconductor layers having different electrical polarization characteristics, and the semiconductor layer with a relatively high polarization rate may induce two-dimensional electron gas 1334 in another semiconductor layer heterogeneously junctioned therewith. The two-dimensional electron gas 1334 may be used as a channel between the source electrode 1373 and the drain electrode 1375, and the continuation or interruption of the flow of this two-dimensional electron gas 1334 can be controlled by the bias voltage applied to the gate electrode 1355. In the gate off state, the flow of the two-dimensional electron gas 1334 is blocked, so a current may not flow between the source electrode 1373 and the drain electrode 1375. As the two-dimensional electron gas 1334 continues to flow in the gate-on state, current may flow between the source electrode 1373 and the drain electrode 1375.

Although the case where the power semiconductor device according to some example embodiments is a normally-off high electron mobility transistor has been described above, the present disclosure is not limited thereto. For example, the power semiconductor device according to some example embodiments may be a normally-on high electron mobility transistor. In the case of the normally-on high electron mobility transistor, the gate semiconductor layer 1352 may be omitted, so the gate electrode 1355 may be positioned directly above the barrier layer 1336. For example, the gate electrode 1355 may contact the barrier layer 1336. In this structure, the two-dimensional electron gas 1334 may be used as a channel while no voltage is applied to the gate electrode 1355, and the flow of current may occur between the source electrode 1373 and the drain electrode 1375. In addition, when a negative voltage is applied to the gate electrode 1355, the depletion area (DPR) in which the flow of the two-dimensional electron gas 1334 is cut off may occur at a lower portion of the gate electrode 1355.

The above-described buffer layer 1322, superlattice layer 1324, high-resistance layer 1326, channel layer 1332, barrier layer 1336, and gate semiconductor layer 1352 are sequentially stacked on the substrate 1310. In the semiconductor device according to some example embodiments, at least one of the buffer layer 1322, the superlattice layer 1324, the high-resistance layer 1326, the channel layer 1332, the barrier layer 1336, and the gate semiconductor layer 1352 may be omitted. The buffer layer 1322, the superlattice layer 1324, the high-resistance layer 1326, the channel layer 1332, the barrier layer 1336, and the gate semiconductor layer 1352 may be made of the same semiconductor material, and the material composition ratio of each layer may be different considering the role of each layer, the performance required for the semiconductor device, etc.

The protective layers 1340, 1360, and 1380 may include a first protective layer 1340, a second protective layer 1360, and a third protective layer 1380.

The first protective layer 1340 may cover an upper surface of the barrier layer 1336 and the first gate electrode 1355a, and may cover side surfaces of the first gate electrode 1355a and the gate semiconductor layer 1352. A lower surface of the first protective layer 1340 may contact the barrier layer 1336, the first gate electrode 1355a, and the gate semiconductor layer 1352. An upper surface of the first protective layer 1340 may be in contact with the second protective layer 1360. The second protective layer 1360 may be spaced apart from the barrier layer 1336, the first gate electrode 1355a, and the gate semiconductor layer 1352 by the first protective layer 1340. Accordingly, the second protective layer 1360 may not contact the barrier layer 1336, the first gate electrode 1355a, and the gate semiconductor layer 1352. The first protective layer 1340 may be positioned on the barrier layer 136 and the first gate electrode 1355a. A first source electrode 173a may be connected to the channel layer 132 by penetrating through the first protective layer 1340. A first drain electrode 175a may be connected to the channel layer 132 by penetrating through the first protective layer 1340.

The second protective layer 1360 may be positioned on the first source electrode 173a and the first drain electrode 175a. The second gate electrode 1355b may be connected to the first gate electrode 1355a by penetrating through the first protective layer 1340 and the second protective layer 1360.

The third protective layer 1380 may be positioned on the second gate electrode 1355b. The third protective layer 1380 may include a third lower protective layer 1380a and a third upper protective layer 1380b.

The third upper protective layer 1380b may be positioned on the third lower protective layer 1380a.

The second source electrode 173b may be connected to the first source electrode 173a by penetrating through the second protective layer 1360 and the third lower protective layer 1380a. The second drain electrode 175b may be connected to the first drain electrode 175a by penetrating through the second protective layer 1360 and the third lower protective layer 1380a. The third source electrode 173c may be connected to the second source electrode 173b by penetrating through the third upper protective layer 1380b. The third drain electrode 175c may be connected to the second drain electrode 175b by penetrating through the third upper protective layer 1380b.

The barrier layer 1336, the first gate electrode 1355a, etc., may be protected by the protective layers 1340, 1360, and 1380 and may be separated from other components. The first protective layer 1340, the second protective layer 1360, and the third protective layer 1380 may include an insulating material. For example, the first protective layer 1340, the second protective layer 1360, and the third protective layer 1380 may include an oxide such as SiO₂ and/or Al₂O₃. As another example, the first protective layer 1340, the second protective layer 1360, and the third protective layer 1380 may include a nitride such as SiN and/or an oxynitride such as SiON. The first protective layer 1340, the second protective layer 1360, and the third protective layer 1380 may include the same material or different materials. When the first protective layer 1340, the second protective layer 1360, and the third protective layer 1380 are made of the same material, a boundary between the first protective layer 1340, the second protective layer 1360, and the third protective layer 1380 may not be visible. The first protective layer 1340, the second protective layer 1360, and the third protective layer 1380 may each be made of a single layer or multiple layers. In some cases, at least one of the first protective layer 1340, the second protective layer 1360, and the third protective layer 1380 may include three or more layers.

The source electrode 1373 and the drain electrode 1375 may be positioned on the channel layer 1332. The source electrode 1373 and the drain electrode 1375 may be spaced apart from each other, and the first gate electrode 1355a and the gate semiconductor layer 1352 may be positioned between the source electrode 1373 and the drain electrode 1375. The first gate electrode 1355a and the gate semiconductor layer 1352 are spaced apart from the source electrode 1373 and the drain electrode 1375. The source electrode 1373 may be electrically connected to the channel layer 1332 on one side of the first gate electrode 1355a. The drain electrode 1375 may be electrically connected to the channel layer 1332 on the other side of the first gate electrode 1355a. The source electrode 1373 and the drain electrode 1375 may be positioned outside the drift area DTR of the channel layer 1332. The boundary between the source electrode 1373 and the channel layer 1332 may be one edge of the drift area DTR. Likewise, the boundary between the drain electrode 1375 and the channel layer 1332 may be the other edge of the drift area DTR. However, it is not limited thereto, and the source electrode 1373 and the drain electrode 1375 may not be positioned outside the drift area DTR of the channel layer 1332. In this case, the channel layer 1332 may not be recessed, and the source electrode 1373 and the drain electrode 1375 may be positioned on an upper surface of the channel layer 1332. The bottom surfaces of the source electrode 1373 and the drain electrode 1375 may contact the upper surface of the channel layer 1332. A portion of the channel layer 1332 that is in contact with the source electrode 1373 and the drain electrode 1375 may be doped at a high concentration. In this case, carriers passing through the two-dimensional electron gas 134 may pass through the highly doped portion of the channel layer 1332, that is, the upper part of the two-dimensional electron gas 1334, and may be transferred to the source electrode 1373 and the drain electrode 1375. The source electrode 1373 and the drain electrode 1375 may not directly contact the two-dimensional electron gas 1334 in the horizontal direction. The horizontal direction may refer to a direction parallel to the upper surface of the channel layer 1332 or the barrier layer 1336.

The source electrode 1373 and the drain electrode 1375 may include a conductive material. For example, the source electrode 1373 and the drain electrode 1375 may include metal, metal alloy, conductive metal nitride, metal silicide, doped semiconductor material, conductive metal oxide, conductive metal nitride, etc. For example, the source electrode 1373 and the drain electrode 1375 may be made of or may include titanium nitride (TiN), tantalum carbide (TaC), tantalum nitride (TaN), titanium silicon nitride (TiSiN), tantalum silicon nitride (TaSiN), tantalum titanium nitride (TaTiN), or titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TIC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof, but are limited thereto. The source electrode 1373 and the drain electrode 1375 may be made of a single layer or multiple layers. The source electrode 1373 and the drain electrode 1375 may be in ohmic contact with the channel layer 1332. An area in contact with the source electrode 1373 and the drain electrode 1375 within the channel layer 1332 may be doped at a relatively high concentration compared to other areas.

The source electrode 1373 may include a first source electrode 1373a, a second source electrode 1373b, and a third source electrode 1373c. The second source electrode 1373b may be positioned on the first source electrode 1373a, and the third source electrode 1373c may be positioned on the second source electrode 1373b. The first source electrode 1373a may be connected to the channel layer 132, the second source electrode 1373b may be connected to the first source electrode 1373a, and the third source electrode 1373c may be connected to the second source electrode 1373b.

The drain electrode 1375 may include a first drain electrode 1375a, a second drain electrode 1375b, and a third drain electrode 1375c. The second drain electrode 1375b may be positioned on the first drain electrode 1375a, and the third drain electrode 1375c may be positioned on the second drain electrode 1375b. The first drain electrode 1375a may be connected to the channel layer 132, the second drain electrode 1375b may be connected to the first drain electrode 1375a, and the third drain electrode 1375c may be connected to the second drain electrode 1375b.

The first source electrode 1373a and the first drain electrode 1375a may be positioned on the first protective layer 1340. The first source electrode 1373a and the first drain electrode 1375a may be positioned between the first protective layer 1340 and the second protective layer 1360. A trench that penetrates through the first protective layer 1340 and the barrier layer 1336 and recesses the upper surface of the channel layer 1332 may be positioned on both sides of the first gate electrode 1355a to be spaced apart from each other. The first source electrode 1373a and the first drain electrode 1375a may be positioned in the trench positioned on both sides of the first gate electrode 1355a, respectively. The first source electrode 1373a and the first drain electrode 1375a may be formed to fill the trench. Within the trench, the first source electrode 1373a and the first drain electrode 1375a may contact the channel layer 1332 and the barrier layer 1336. The channel layer 1332 may form a bottom surface and side walls of the trench, and the barrier layer 1336 may form the side walls of the trench. Accordingly, the first source electrode 1373a and the first drain electrode 1375a may contact the upper surface and side surfaces of the channel layer 1332. Alternatively or additionally, the first source electrode 1373a and the first drain electrode 1375a may contact the side surfaces of the barrier layer 1336. That is, the first source electrode 1373a and the first drain electrode 1375a may cover the side surfaces of the channel layer 1332 and the barrier layer 1336. The upper surface of the first source electrode 1373a and the first drain electrode 1375a may protrude from the upper surface of the first protective layer 1340. Alternatively or additionally, at least one of the first source electrode 1373a and the first drain electrode 1375a may cover at least a portion of the upper surface of the first protective layer 1340. The second protective layer 1360 may be positioned on the first source electrode 1373a and the first drain electrode 1375a. At least a portion of the first source electrode 1373a and the first drain electrode 1375a may be covered by the second protective layer 1360. At least a portion of the first source electrode 1373a and the first drain electrode 1375a may be in contact with the second lower protective layer 1360a and may not be in contact with the second upper protective layer 1360b.

The second source electrode 1373b and the second drain electrode 1375b may be positioned on the third lower protective layer 1380a. An opening penetrating through the second protective layer 1360 and the third lower protective layer 1380a may be positioned to overlap the first source electrode 1373a, and the second source electrode 1373b may be positioned within the opening. The second source electrode 1373b may be formed to fill the opening. Within the opening, the second source electrode 1373b may be in contact with the first source electrode 1373a. The second source electrode 1373b may be connected to the first source electrode 1373a through the opening. Another opening penetrating through the second protective layer 1360 and the third lower protective layer 1380a may be positioned to overlap the first drain electrode 1375a, and the second drain electrode 1375b may be positioned within the opening.

The second drain electrode 1375b may be formed to fill the opening.

Within the opening, the second drain electrode 1375b may be in contact with the first drain electrode 1375a. The second drain electrode 1375b may be connected to the first drain electrode 1375a through the opening.

The upper surface of the second source electrode 1373b and the second drain electrode 1375b may protrude from the upper surface of the third lower protective layer 1380a. Alternatively or additionally, at least one of the second source electrode 1373b and the second drain electrode 1375b may cover at least a portion of the upper surface of the third lower protective layer 1380a.

The opening filled with the second source electrode 1373b may overlap the trench filled with the first source electrode 1373a. However, example embodiments are not limited thereto, and in some cases, the opening and the trench may not overlap. The opening filled with the second source electrode 1373b may completely overlap the first source electrode 1373a. However, example embodiments are not limited thereto, and in some cases, at least a portion of the opening filled with the second source electrode 1373b may not overlap with the first source electrode 1373a. In this case, the second source electrode 1373b may cover the side surface of the first source electrode 1373a and may contact the upper surface of the first protective layer 1340. A width of the opening filled with the second source electrode 1373b may be similar to that of the trench filled with the first source electrode 1373a. However, the relationship between the width of the opening and the width of the trench is not limited thereto and may change in various ways.

The opening filled with the second drain electrode 1375b may overlap the trench filled with the first drain electrode 1375a. However, it is not limited thereto, and in some cases, the opening and the trench may not overlap. The opening filled with the second drain electrode 1375b may completely overlap the first drain electrode 1375a. However, example embodiments are not limited thereto, and in some cases, at least a portion of the opening filled with the second drain electrode 1375b may not overlap with the first drain electrode 1375a. In this case, the second drain electrode 1375b may cover the side surface of the first drain electrode 1375a and may contact the upper surface of the first protective layer 1340. The width of the opening filled with the second drain electrode 1375b may be similar to that of the trench filled with the first drain electrode 1375a. However, the relationship between the width of the opening and the width of the trench is not limited thereto and may change in various ways.

The semiconductor device according to some example embodiments may further include a field dispersion layer 1377 positioned on the third lower protective layer 1380a. The field dispersion layer 1377 may be positioned between the source electrode 1373 and the drain electrode 1375. The field dispersion layer 1377 may overlap the second gate electrode 1355b in the vertical direction. The second gate electrode 1355b may be covered by the field dispersion layer 1377. The field dispersion layer 1377 may be wider than the width of the second gate electrode 1355b. However, it is not limited thereto, and the width and positional relationship of the field dispersion layer 1377 may change in various ways. The field dispersion layer 1377 may be electrically connected to the source electrode 1373. For example, the field dispersion layer 1377 may be connected to the second source electrode 1373b. The field dispersion layer 1377 may include the same material as the second source electrode 1373b and may be positioned on the same layer as the second source electrode 1373b. The field dispersion layer 1377 may be formed simultaneously with the second source electrode 1373b in the same process. The boundary between the field dispersion layer 1377 and the second source electrode 1373b is not clear, and the field dispersion layer 1377 may be formed integrally with the second source electrode 1373b. However, example embodiments are not limited thereto, and the field dispersion layer 1377 may be a separate component from the second source electrode 1373b. In addition, the field dispersion layer 1377 may be positioned in a different layer from the second source electrode 1373b and may be formed in a different process. In some cases, the field dispersion layer 1377 may be electrically connected to the second gate electrode 1355b. In some cases, an additional field dispersion layer may be positioned on the second protective layer 1360 and/or the first protective layer 1340.

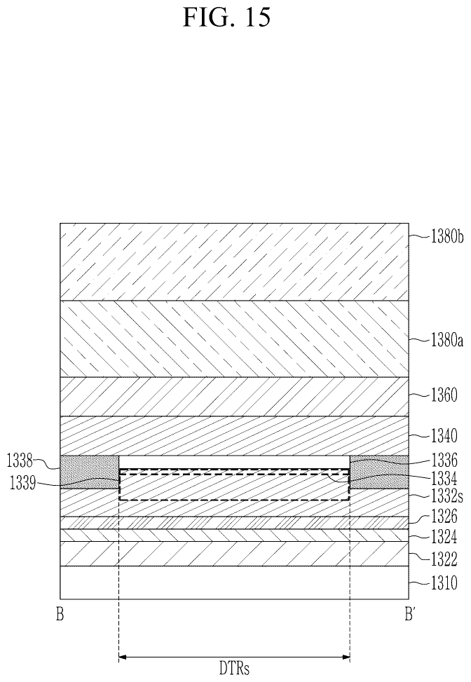

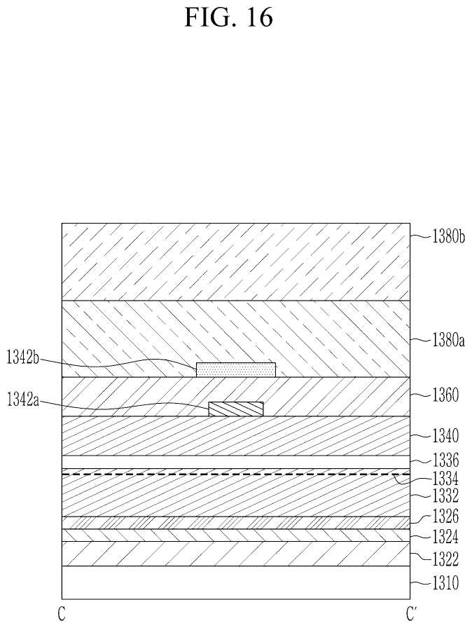

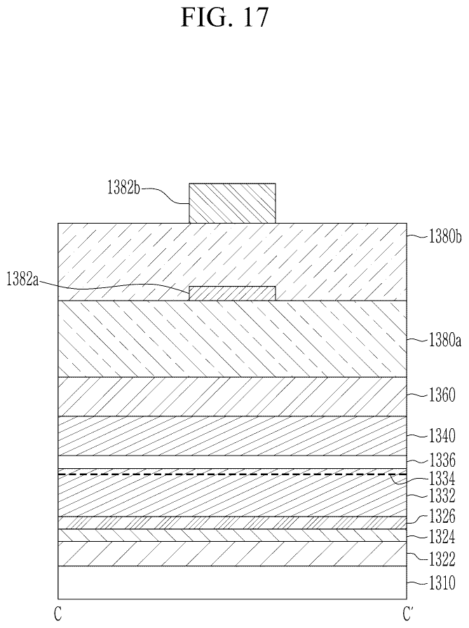

FIG. 15 is a cross-sectional view taken along line B-B′ of FIG. 13. FIG. 16 is a cross-sectional view taken along line C-C′ of FIG. 13. FIG. 17 is a cross-sectional view taken along line D-D′ of FIG. 13.

Referring to FIGS. 13 and 15 to 17, a peripheral circuit element 1302 of the power semiconductor device according to some example embodiments may correspond to the surge protection circuit 322 of FIG. 3. The peripheral circuit element 1302 of the power semiconductor device according to some example embodiments may include voltage distribution circuit areas 1339 and 1341 connected to the source electrode 1373 and the drain electrode 1375, a digitizer circuit region 1342 connected to the voltage distribution circuit areas 1339 and 1341, and a protection circuit area 1382 connected to the source electrode 1373 and the drain electrode 1375.

In FIG. 15, a sub-channel layer 1332s may be positioned on the substrate 1310, and a buffer layer 1322, a superlattice layer 1324, and a high-resistance layer 1326, etc., may be positioned between the substrate 1310 and the sub-channel layer 1332s. The barrier layer 1336 may be positioned on the sub-channel layer 1332s. The voltage divider circuit area 1339 may include resistors R1 and R2 of FIG. 5. In some example embodiments, the resistors R1 and R2 may include a sub-channel layer 1332s.

The sub-channel layer 1332s may be positioned on the substrate 1310. A two-dimensional electron gas (2 DEG) 1334 may be positioned inside the sub-channel layer 1332s. The two-dimensional electron gas 1334 may be generated at the interface between the sub-channel layer 1332s and the barrier layer 1336 in the power semiconductor device according to some example embodiments. For example, the two-dimensional electron gas 1334 may be generated in a portion adjacent to the barrier layer 1336 within the sub-channel layer 1332s.

The sub-channel layer 1332s may be connected to the source electrode 1373 and the drain electrode 1375. The sub-channel layer 1332s may include a plurality of parts extending in a first direction (X direction) and a plurality of parts extending in a second direction (Y direction). For example, as illustrated in FIG. 4, the sub-channel layer 1332s includes a portion extending in the first direction (X direction) from a point (a point connected to the source electrode 1373) connected to the drain electrode 1375, and a portion extending in the second direction (Y direction), which are positioned alternately. This may be a shape to secure the length of the sub-channel layer 1332s in a unit area. However, this is only an example, and the extension direction of the sub-channel layer 1332s is not limited thereto. For example, the sub-channel layer 1332s may extend from one side of the channel layer 1332 in only one direction or may include a plurality of bent portions. Alternatively, the sub-channel layer 1332s may include a portion extending in an arbitrary direction crossing the first and second directions. In some example embodiments, the sub-channel layer 1332s may be extended to have a predetermined length. Here, the extending length of the sub-channel layer 1332s may refer to the total sum of the length over which the subchannel layer 1332s extends. In this case, the width of the sub-channel layer 1332s may be smaller than that of the channel layer 1332. Here, the width of the sub-channel layer 1332s may refer to the width along the direction perpendicular to the extension direction of the sub-channel layer 1332s. The width of the channel layer 1332 may refer to the width of the channel layer 1332 in the second direction.

In some example embodiments, one end of the sub-channel layer 1332s may contact the first drain electrode 1375a. The sub-channel layer 1332s may be electrically connected to the drain electrode 1375 through the first drain electrode 1375a.

In some example embodiments, the other end of the sub-channel layer 1332s may contact the first source electrode 1373a. The sub-channel layer 1332s may be electrically connected to the source electrode 1373 through the first source electrode 1373a.

In some example embodiments, the sub-channel layer 1332s may be formed integrally with the channel layer 1332 of the transistor 1300 through the same process. The sub-channel layer 1332s may be positioned on the same layer as the channel layer 1332. The lower surface of the sub-channel layer 1332s may be positioned at the same level as the lower surface of the channel layer 1332, and the upper surface of the sub-channel layer 1332s may be positioned at the same level as the upper surface of the channel layer 1332. For example, the lower surface of the sub-channel layer 1332s may be positioned at the same distance from the lower surface of the channel layer 1332 and the upper surface of the substrate 1310. example embodiments are, the upper surface of the sub-channel layer 1332s may be positioned at the same distance from the upper surface of the channel layer 1332. The thickness of the sub-channel layer 1332s along the third direction (Z-direction) may be substantially the same as the thickness of the channel layer 1332 along the third direction (Z-direction), but is not limited thereto. The sub-channel layer 1332s may refer to a portion of the channel layer 1332 positioned in a peripheral circuit area (PA).

In some example embodiments, the sub-channel layer 1332s may include the same material as the channel layer 1332 positioned in the device area MA. As an example, the sub-channel layer 1332s may include one or more materials selected from group III-V materials, such as nitrides including Al, Ga, In, B, or a combination thereof.

The barrier layer 1336 may be positioned on the sub-channel layer 1332s. The barrier layer 1336 may be positioned directly above the sub-channel layer 1332s. However, it is not limited thereto, and another predetermined layer may be further positioned between the sub-channel layer 1332s and the barrier layer 1336. The area of the sub-channel layer 1332s that overlaps the barrier layer 1336 may be a drift area. Specifically, the barrier layer 1336 is different from the sub-channel layer 1332s in at least one of polarization characteristics, energy band gap, or lattice constant, so the two-dimensional electron gas 1334 may be induced in the subchannel layer 1332s, which has a relatively low electrical polarization rate, by the barrier layer 1336.

In some example embodiments, in the peripheral circuit area PA, the sub-channel layer 1332s may include sub-drift areas DTRs between the separation structures 1338. In some cases, the sub-drift areas DTRs may refer to the area of the sub-channel layer 1332s from one side of the sub-channel layer 1332s in contact with the drain electrode 1375 to the other side of the sub-channel layer 1332s in contact with the source electrode 1373.

The sub-drift areas DTRs may refer to an area of the sub-channel layer 1332s that overlaps the barrier layer 1336 between the source electrode 1373 and the drain electrode 1375.

For example, the boundary where the drain electrode 1375 and the sub-channel layer 1332s meet may be one edge of the sub-drift areas DTRs, and the boundary where the source electrode 1373 and the sub-channel layer 1332s meet may be the edge of the sub-drift area (DTRs).

In other words, the sub-drift areas DTRs may refer to an area where carriers move between one side of the sub-channel layer 1332s in contact with the drain electrode 1375 and the other side of the sub-channel layer 1332s in contact with the source electrode 1373 within the peripheral circuit area PA.

In some example embodiments, the sub-drift areas DTRs of the sub-channel layer 1332s may include a plurality of portions extending in a first direction (X direction) and a plurality of portions extending in a second direction (Y direction). For example, to overlap in plan with the sub-channel layer 1332s illustrated in FIG. 13, the sub-drift areas DTRs may have a portion extending in a first direction (X direction) and a portion extending in a second direction (Y direction) from one side of the drain electrode 1375 which are positioned alternately. This may be a shape to secure the length of sub-drift areas DTRs in a unit area. However, this is only an example, and the extending direction of the sub-drift areas DTRs is not limited thereto.

The sub-drift areas DTRs may have a resistance component. That is, the sub-drift areas DTRs may function as resistance devices (R1 and/or R2 in FIG. 5) having a predetermined resistance value. That is, the area of the sub-channel layer 1332s from the drain electrode 1375 to the source electrode 1373 may have a predetermined resistance value.

The protective layer 1340 may be positioned on barrier layer 1336. The lower surface of the protective layer 1340 may be in contact with the barrier layer 1336. In some example embodiments, the protective layer 1340 may be formed integrally with the protective layer 1340 of the device area MA through the same process. That is, the protective layer 1340 may be positioned on the barrier layer 1336 in the device area MA and the barrier layer 1336 in the peripheral circuit area PA.

In some example embodiments, the peripheral circuit element 1302 may be separated from transistor 1300 by the separation structure 1338. That is, the separation structure 1338 may be positioned between the peripheral circuit element 1302 and the transistor 1300. For example, the separation structure 1338 may separate the channel layer 1332 and the sub-channel layer 1332s from each other. The separation structure 1338 may recess at least a portion of the sub-channel layer 1332s by penetrating through the barrier layer 1336, but is not limited thereto. Accordingly, the sub-drift areas DTRs of the peripheral circuit element 1302 may be electrically insulated from the transistor 1300. However, example embodiments are not limited thereto, and as another example, the separation structure 1338 may penetrate through the barrier layer 1336 and the sub-channel layer 1332s. Alternatively or additionally, the peripheral circuit element 1302 and the transistor 1300 may be separated by a trench penetrating through at least a portion of the sub-channel layer 1332s and/or the channel layer 1332.

In some example embodiments, the separation structure 1338 may form the barrier layer 1336 on the channel layer 1332 and the sub-channel layer 1332s, and may be formed by performing an ion implant process within the barrier layer 1336 positioned between the transistor 1300 and the peripheral circuit element 1302. However, example embodiments are not limited thereto, and the separation structure 1338 is formed by forming a barrier layer 1336 on the channel layer 1332 and the sub-channel layer 1332s, forming the trench penetrating through the barrier layer 1336, and then filling the trench with the insulating material. The insulating material constituting the separation structure 1338 may include the same material as the protective layer 1340. For example, the insulating material constituting the separation structure 1338 may include an oxide such as SiO₂ and/or Al₂O₃. As another example, the insulating material constituting the separation structure 1338 may include a nitride such as SiN or an oxynitride such as SiON. However, example embodiments are not limited thereto, and the insulating material constituting the separation structure 1338 may include a material different from the protective layer 1340. In this case, at least a portion of the channel layer 1332 and/or the sub-channel layer 1332s may be recessed together.

In FIG. 16, the digitizer area 1341 may include the capacitor C5 of FIG. 9. In some example embodiments, a capacitor C5 may include a first electrode 1342a and a second electrode 1342b.

The first electrode 1342a may be positioned on the first protective layer 1340. The second electrode 1342b may be positioned on the second protective layer 1360. The first electrode 1342a and the second electrode 1342b may overlap each other on the XY plane. The first electrode 1342a and the second electrode 1342b may include a conductive material. For example, the first electrode 1342a and the second electrode 1342b may include metal, metal alloy, conductive metal nitride, metal silicide, doped semiconductor material, conductive metal oxide, conductive metal nitride, etc. For example, the first electrode 1342a and the second electrode 1342b may be made of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), Nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof, but are limited thereto. The first electrode 1342a and the second electrode 1342b may be made of a single layer or multiple layers.

In FIG. 17, the protection circuit area 1382 may include a capacitor C6 of FIG. 10. In some example embodiments, the capacitor C6 may include a first electrode 1382a and a second electrode 1382b. One of the first electrode 1382a and the second electrode 1382b may be connected to the drain electrode 1375, and the other of the first electrode 1382a and the second electrode 1382b may be connected to the first transistor (Q7 in FIG. 10).

The first electrode 1382a may be positioned on the third lower protective layer 1380a. The second electrode 1382b may be positioned on the third upper protective layer 1380b. The first electrode 1382a and the second electrode 1382b may overlap each other on the XY plane. The first electrode 1382a and the second electrode 1382b may include a conductive material. For example, the first electrode 1382a and the second electrode 1382b may include metal, metal alloy, conductive metal nitride, metal silicide, doped semiconductor material, conductive metal oxide, conductive metal nitride, etc. For example, the first electrode 1382a and the second electrode 1382b may be made of titanium nitride (TiN), tantalum carbide (TaC), tantalum nitride (TaN), titanium silicon nitride (TiSiN), tantalum silicon nitride (TaSiN), tantalum titanium nitride (TaTiN), or titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TIC), tantalum carbonitride (TaCN), tungsten (W), aluminum (Al), copper (Cu), cobalt (Co), titanium (Ti), tantalum (Ta), nickel (Ni), platinum (Pt), Nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof, but are limited thereto. The first electrode 1382a and the second electrode 1382b may be made of a single layer or multiple layers.

In the above, the capacitor C6 of FIG. 10 was described as an example, but the capacitors C1 and C2 of FIG. 5 and the capacitors C3 and C4 of FIG. 6 may include the first electrode 1382a and the second electrode 1382b.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While inventive concepts have been described in connection with what is presently considered to be practical example embodiments, it is to be understood that the inventions are not limited to the disclosed example embodiments. On the contrary, it is intended to cover various modifications and equivalent arrangements included within the spirit and scope of the appended claims. Furthermore example embodiments are not necessarily mutually exclusive with one another. For example, some example embodiments may include one or more features described with reference to one or more figures, and may also include one or more other features described with reference to one or more other figures.

What is claimed is:

1. A semiconductor device, comprising:
a high electron mobility transistor including a gate configured to receive a gate signal, a drain connected to a first terminal, and a source connected to a second terminal; and
a surge protection circuit configured to change an output capacitance of the high electron mobility transistor based on a voltage between the drain and the source.

2. The semiconductor device of claim 1, wherein the surge protection circuit includes:
a voltage divider circuit connected between the drain and the source and configured to output a dividing voltage that divides the voltage;
a digitizer circuit configured to output at least one of a first voltage or a second voltage lower than the first voltage based on the dividing voltage divided by the voltage divider circuit; and
a protection circuit connected between the drain and the source and configured to change the output capacitance based on the at least one of the first voltage or the second voltage that is output by the digitizer circuit.

3. The semiconductor device of claim 2, wherein
the protection circuit includes:
a first capacitor and a first transistor connected in series between the drain and the source of the high electron mobility transistor, and
the first transistor includes a gate configured to receive the at least one of the first voltage or the second voltage output by the digitizer circuit.

4. The semiconductor device of claim 2, wherein
the voltage divider circuit includes at least one of first and second resistors connected in series between the drain and the source of the high electron mobility transistor, or first and second capacitors connected in series between the drain and the source of the high electron mobility transistor.

5. The semiconductor device of claim 2, wherein
the voltage divider circuit includes
a first capacitor and a second capacitor connected in series between the drain and the source of the high electron mobility transistor, and
a first transistor connected between one electrode of the second capacitor and another electrode of the second capacitor and having a gate configured to receive the gate signal.

6. The semiconductor device of claim 2, wherein the digitizer circuit includes a plurality of inverter circuits connected between an output terminal of the voltage divider circuit and an input terminal of the protection circuit.

7. The semiconductor device of claim 6, wherein the inverter includes:
a first transistor connected between the output terminal and a first node configured to be at the second voltage and including a gate connected to the input terminal; and
a first resistor connected between the output terminal and a second node configured to be at the first voltage.

8. The semiconductor device of claim 6, wherein the inverter includes:
a first transistor connected between the output terminal and the first voltage;
a second transistor connected between a gate of the first transistor and a first node configured to be at the first voltage and including a gate connected to the first node;
a third transistor connected between the output terminal and a second node configured to be at the second voltage and including a gate connected to the input terminal; and
a first capacitor connected between the gate of the first transistor and the output terminal.

9. A power semiconductor device, comprising:
a high electron mobility transistor including a channel layer, a barrier layer on the channel layer and including a material having an energy band gap different from that of the channel layer, a gate electrode on the barrier layer, a gate semiconductor layer between the barrier layer and the gate electrode, and a source electrode on a first side of and a drain electrode on a second side of the gate electrode and the source electrode and the drain electrode connected to the channel layer;
a first capacitor including a first electrode on a first protective layer on the barrier layer, a second protective layer on the first electrode, and a second electrode on the second protective layer; and
a first transistor connecting the first capacitor between the drain electrode and the source electrode, the connecting based on a voltage between the drain electrode and the source electrode.

10. The power semiconductor device of claim 9, wherein:
one of the first electrode and the second electrode is connected to the drain electrode, and the other of the first electrode and the second electrode is connected to the first transistor.

11. The power semiconductor device of claim 9, further comprising:
a second capacitor including a third electrode on the first protective layer and a fourth electrode on a third protective layer between the barrier layer and the first protective layer.

12. The power semiconductor device of claim 11, wherein the source electrode includes:
a first source electrode on the third protective layer;
a second source electrode on the first protective layer; and
a third source electrode on the second protective layer, and
the drain electrode includes:
a first drain electrode on the third protective layer;
a second drain electrode on the first protective layer; and
a third drain electrode on the second protective layer.

13. The power semiconductor device of claim 9, further comprising:
a resistor including a sub-channel layer connected between the drain electrode and the source electrode and including a drift region with two-dimensional electron gas.

14. The power semiconductor device of claim 13, wherein the voltage between the drain electrode and the source electrode is configured to be divided by the resistor.

15. The power semiconductor device of claim 13, wherein the channel layer and the sub-channel layer are separated from each other by a separation structure penetrating through the barrier layer.

16. A power semiconductor system, comprising:
a switch controller configured to receive a first driving voltage, a second driving voltage, and a control signal, and to output a gate signal based on the first driving voltage, the second driving voltage, and the control signal; and
a power block including a high electron mobility transistor connected between a first power supply voltage and a second power supply voltage configured to be at a level lower than the first power supply voltage, and configured to receive the gate signal as an input and a surge protection circuit connected between a source and a drain of the high electron mobility transistor, and configured to control an output capacitance of the high electron mobility transistor.

17. The power semiconductor system of claim 16, wherein the surge protection circuit includes:
a first transistor including a gate configured to receive a voltage corresponding to a voltage difference between the source and the drain of the high electron mobility transistor; and
an output capacitor including one electrode connected to the drain of the high electron mobility transistor and another electrode connected to the drain of the first transistor.

18. The power semiconductor system of claim 17, wherein the surge protection circuit further includes:
a voltage divider circuit configured to divide a voltage difference between the source and the drain; and
a digitizer circuit configured to output a first voltage and a second voltage lower than the first voltage based on the voltage divided by the voltage divider circuit, and
the first transistor configured to turn on in response to the first voltage being applied and to turn off in response to the second voltage being applied.

19. The power semiconductor system of claim 18, wherein the digitizer circuit is further configured to output the first voltage in response to the voltage distributed by the voltage division circuit exceeding a threshold voltage, and to output the second voltage in response to the voltage divided by the voltage divider circuit being less than the threshold voltage.

20. The power semiconductor system of claim 16, wherein:
the switch controller includes a gate driver configured to output the first driving voltage to turn on the high electron mobility transistor or the second driving voltage to turn off the high electron mobility transistor, based on the control signal.
